(19) United States
(12) Patent Application Publication
(10) Pub. No.: US 2025/0093450 A1
(43) Pub. Date: Mar. 20, 2025

(54) SIGNAL PROCESSING CIRCUIT, MEASUREMENT INSTRUMENT, AND METHOD OF DETERMINING A SYMBOL ERROR RATE

(71) Applicant: Rohde & Schwarz GmbH & Co. KG, Muenchen (DE)

(72) Inventors: Florian RAMIAN, Muenchen (DE); Susanne HIRSCHMANN, Muenchen (DE)

(73) Assignee: Rohde & Schwarz GmbH & Co. KG, Muenchen (DE)

(21) Appl. No.: 18/469,974

(22) Filed: Sep. 19, 2023

(51) Int. Cl. G01R 35/00

(52) U.S. Cl. CPC G01R 35/00

(57) ABSTRACT

A signal processing circuit includes an input interface and an analysis circuit. The input interface is configured to receive a measurement signal and a reference signal. The input interface further is configured to forward the measurement signal and the reference signal to the analysis circuit. The measurement signal and the reference signal include a symbol sequence, respectively. The analysis circuit is configured to synchronize the measurement signal with the reference signal. The analysis circuit is configured to determine error vectors based on the synchronized measurement signal and reference signal. The analysis circuit further is configured to determine symbol points of the symbol sequence and decision boundaries for the symbol points. The analysis circuit further is configured to determine whether the determined error vectors exceed the decision boundaries determined. Further, a measurement instrument and a method of determining a symbol error rate of a measurement signal are described.

### FIELD OF THE DISCLOSURE

Embodiments of the present disclosure generally relate to a signal processing circuit. Embodiments of the present disclosure further relate to a measurement instrument and to a method of determining a symbol error rate of a measurement signal.

### BACKGROUND

Symbol error rate (SER) measurements and bit error rate (BER) measurements are common tests performed on devices under test, as they are a direct measure for the performance of the device under test.

Traditionally, SER/BER measurements are performed using a process known as demodulation, which requires a known symbol reference. This method, however, necessitates an exact knowledge of the system, as the demodulation process requires the input of modulation parameters. This can be a significant challenge, for example in the Aerospace and Defense (A&D) environment, where not every component supplier may have a complete understanding of all signal details.

In addition, under real operating conditions, the modulation parameters may change, e.g. depending on a requested throughput and/or depending on signal-to-noise ratio conditions, which further complicates the SER/BER measurements to be conducted.

Accordingly, there is a need for a signal processing circuit, a measurement instrument, and a method of determining a symbol error rate of a measurement signal that require less knowledge about the signal to be measured.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a signal processing circuit. In an embodiment, the signal processing circuit comprises an input interface and an analysis circuit. The input interface is configured to receive a measurement signal and a reference signal. The input interface further is configured to forward the measurement signal and the reference signal to the analysis circuit. The measurement signal and the reference signal comprise a symbol sequence, respectively. The analysis circuit is configured to synchronize the measurement signal with the reference signal. The analysis circuit is configured to determine error vectors based on the synchronized measurement signal and reference signal. The analysis circuit further is configured to determine symbol points of the symbol sequence and decision boundaries for the symbol points. The analysis circuit further is configured to determine whether the determined error vectors exceed the decision boundaries determined.

The term “synchronize the measurement signal with the reference signal” is understood to denote that the symbol sequences comprised in the measurement signal and in the reference signal are aligned with each other.

In some embodiments, the measurement signal and the reference signal comprise the same symbol sequence. Accordingly, synchronizing the measurement signal with the reference signal means that the same symbols occur at the same time.

Further, the term “decision boundary” is understood to denote a boundary in the symbol plane (also called “constellation plane”) outside of which the symbol cannot be identified unambiguously. Conversely, the decision boundary denotes a boundary in the symbol plane inside of which the symbol can be identified unambiguously.

Moreover, the term “symbol point” is understood to denote the time at which the respective symbol is detected. For example, the symbol point may be the time at which the input signal crosses a decision threshold that is associated with a certain signal value.

The measurement signal and/or the reference signal may be, for example, a binary signal, such that there are two different possible symbol values for the symbols in the symbol sequence. However, in other embodiments, the symbols of the symbol sequence may have more than two different possible symbol values.

The measurement signal and/or the reference signal may be an N-ary amplitude phase-shift keying (N-APSK) modulated signal, wherein N is an integer equal to or greater than 2. In a certain example, the measurement signal and/or the reference signal may be a binary phase-shift keying (BPSK) modulated signal, or a quaternary phase-shift keying (QPSK) modulated signal.

The signal processing circuit according to embodiments of the present disclosure allow to determine a symbol error rate (SER) of the measurement signal without demodulating the measurement signal. This is achieved by synchronizing the measurement signal with the reference signal, determining error vectors, determining symbol points of the symbol sequence and decision boundaries for the symbol points, and determining whether the determined error vectors exceed the decision boundaries determined.

If an error vector at one of the determined symbol points exceeds the respective decision boundary, the corresponding symbol is erroneous and the SER may be incremented by one. Accordingly, by counting the number of error vectors exceeding the respective decision boundaries at the symbol points, the SER of the measurement signal can be determined without demodulating the measurement signal.

Thus, the signal processing circuit according to embodiments of the present disclosure allows to determine the SER of the measurement signal with less knowledge about the measurement signal, thereby enabling SER measurements even under conditions with changing modulation parameters.

It is emphasized that no demodulation of the measurement signal and/or of the reference signal is required in order determine the symbol points. Instead, the symbol points and the measurement times are determined directly based on the reference signal or received samples associated with the reference signal.

According to an aspect of the present disclosure, the analysis circuit is configured, for example, to determine the number of error vectors exceeding the decision boundaries. In some embodiments, the analysis circuit is configured to determine the number of error vectors exceeding the decision boundaries at the symbol points. The number of error vectors exceeding the decision boundaries at the symbol points corresponds to the number of symbol errors comprised in the measurement signal.

In an embodiment of the present disclosure, the analysis circuit is configured to determine a symbol error rate (SER) based on the determined number of error vectors exceeding the decision boundaries. In some embodiments, the SER of the measurement signal can be determined by dividing the number of error vectors exceeding the decision boundaries at the symbol points by the total number of symbols analyzed.

For a measurement signal having only two different possible symbols, e.g. 0 and 1, the SER is a bit error rate (BER).

According to another aspect of the present disclosure, the analysis circuit is configured, for example, to determine a modulation scheme of the measurement signal based on the measurement signal and/or based on the reference signal. It is noted that determining the modulation scheme is not tantamount to demodulating the signal, i.e. the modulation scheme can be determined without demodulating the measurement signal.

In a further embodiment of the present disclosure, the decision boundaries are determined based on the determined modulation scheme. Usually, different modulation schemes have different decision boundaries associated with the symbols. By determining the modulation scheme, the decision boundaries can be determined by an appropriate method, e.g. by a lookup table comprising different modulation schemes and associated decision boundaries.

A further aspect of the present disclosure provides that the signal processing circuit is configured, for example, to transform the determined decision boundaries to an origin of a constellation plane. For example, the determined decision boundaries may be transformed such that geometric centers of the decision boundaries are shifted to the origin of the constellation plane. This way, it is particularly easy to determine whether the determined error vectors exceed the decision boundaries at the symbol points.

In some embodiments, the constellation plane is an IQ plane. Accordingly, the measurement signal may be an IQ-modulated signal.

In an embodiment of the present disclosure, the measurement signal is a digital file or a digital data stream. Thus, the measurement signal may be played back from a memory in which the digital file is saved. Alternatively, the measurement signal may be received from another electronic device streaming the digital data stream, e.g. from a server or from another measurement instrument.

Accordingly, the signal processing circuit may be configured to determine the SER of the measurement signal by a post-processing of the measurement signal.

An aspect of the present disclosure provides that the measurement signal is, for example, a radio frequency (RF) signal obtained by a measurement, and/or that the reference signal is a radio frequency signal obtained by a measurement. In other words, the signal processing circuit may analyze a measured RF signal in real time, thereby enabling real-time SER measurements.

Embodiments of the present disclosure further provide a measurement instrument. The measurement instrument comprises a signal processing circuit according to any one of the embodiments described above.

Regarding the advantages and further properties of the measurement instrument, reference is made to the explanations given above with respect to the signal processing circuit, which also hold for the measurement instrument and vice versa.

According to an aspect of the present disclosure, the measurement instrument is, for example, a signal analyzer, a spectrum analyzer, an oscilloscope, or a vector network analyzer. However, it is to be understood that the measurement instrument may be established as any other suitable type of measurement instrument.

Embodiments of the present disclosure further provide a method of determining a symbol error rate of a measurement signal. The method comprising the steps of receiving, by an input interface, a measurement signal and a reference signal, wherein the measurement signal and the reference signal comprise a symbol sequence, respectively; synchronizing, by an analysis circuit, the measurement signal with the reference signal; determining, by the analysis circuit, error vectors based on the synchronized measurement signal and reference signal; determining, by the analysis circuit, symbol points of the symbol sequence and decision boundaries for the symbol points; and determining, by the analysis circuit, whether the determined error vectors exceed the decision boundaries determined.

In some embodiments, the signal processing circuit and/or the measurement instrument described above are/is configured to perform the method of determining a symbol error rate of a measurement signal.

Regarding the advantages and further properties of the method, reference is made to the explanations given above with respect to the signal processing circuit and with respect to the measurement instrument, which also hold for the method and vice versa.

According to an aspect of the present disclosure, the number of error vectors, for example, exceeding the decision boundaries is determined by the analysis circuit. In some embodiments, the number of error vectors exceeding the decision boundaries at the symbol points is determined by the analysis circuit. The number of error vectors exceeding the decision boundaries at the symbol points corresponds to the number of symbol errors comprised in the measurement signal.

In an embodiment of the present disclosure, a symbol error rate (SER) is determined based on the determined number of error vectors exceeding the decision boundaries by the analysis circuit. In some embodiments, the SER of the measurement signal can be determined by dividing the number of error vectors exceeding the decision boundaries at the symbol points by the total number of symbols analyzed.

According to another aspect of the present disclosure, a modulation scheme of the measurement signal is determined, for example, based on the measurement signal and/or based on the reference signal by the analysis circuit. It is noted that determining the modulation scheme is not tantamount to demodulating the signal, i.e. the modulation scheme can be determined without demodulating the measurement signal.

The decision boundaries may be determined based on the determined modulation scheme. Usually, different modulation schemes have different decision boundaries associated with the symbols. By determining the modulation scheme, the decision boundaries can be determined by an appropriate method, e.g. by a lookup table comprising different modulation schemes and associated decision boundaries.

In a further embodiment of the present disclosure, the determined decision boundaries are transformed to an origin of a constellation plane by the analysis circuit. For example, the determined decision boundaries may be transformed such that geometric centers of the decision boundaries are shifted to the origin of the constellation plane. This way, it is particularly easy to determine whether the determined error vectors exceed the decision boundaries at the symbol points.

According to a further aspect of the present disclosure, the constellation plane is, for example, an IQ plane. Accordingly, the measurement signal may be an IQ-modulated signal.

In some embodiments, the measurement signal is a digital file or a digital data stream. Thus, the measurement signal may be played back from a memory in which the digital file is saved. Alternatively, the measurement signal may be received from another electronic device streaming the digital data stream, e.g. from a server or from another measurement instrument. Accordingly, the SER of the measurement signal may be determined by a post-processing of the measurement signal.

Another aspect of the present disclosure provides that the measurement signal is, for example, a radio frequency signal obtained by a measurement, and/or that the reference signal is a radio frequency signal obtained by a measurement. In other words, the measures RF signal may be analyzed in real time, thereby enabling real-time SER measurements.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement instrument according to an embodiment of the present disclosure;

FIG. 2 schematically shows an example of the signal processing circuit of the measurement instrument of FIG. 1;

FIG. 3 shows a flow chart of a method of determining a symbol error rate of a measurement signal according to an embodiment of the present disclosure;

FIG. 4 shows a diagram illustrating a step of the method of FIG. 3;

FIG. 5 shows a diagram illustrating a further step of the method of FIG. 3; and

FIG. 6 shows a diagram illustrating a further step of the method of FIG. 3.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

Similarly, any steps described herein may be interchangeable with other steps, or combinations of steps, in order to achieve the same or substantially similar result. Moreover, some of the method steps can be carried serially or in parallel, or in any order unless specifically expressed or understood in the context of other method steps.

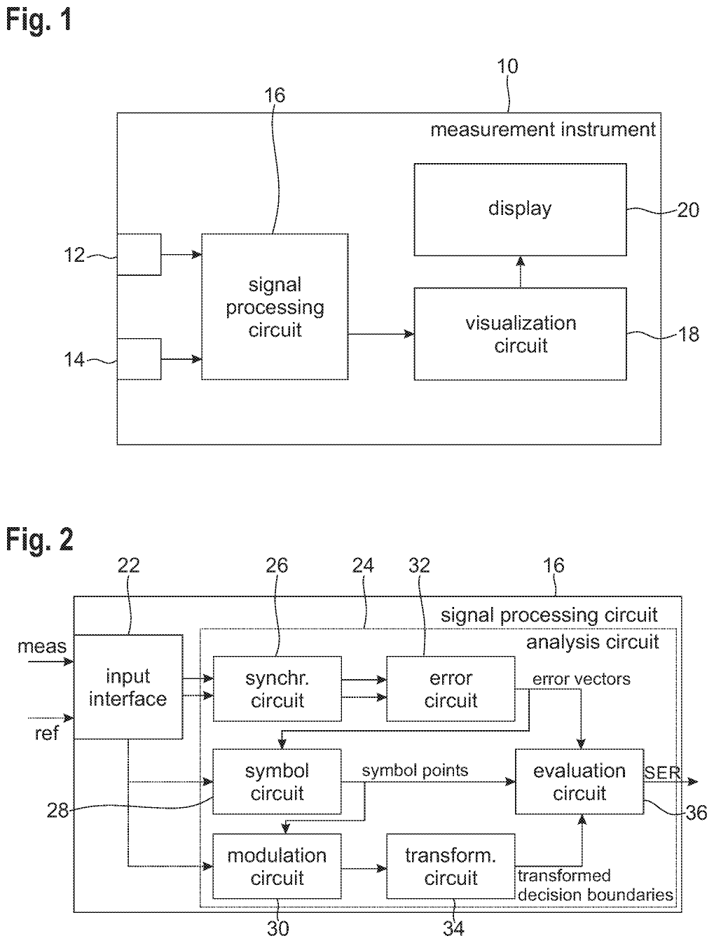

FIG. 1 schematically shows a measurement instrument 10 in accordance with an embodiment of the present disclosure. In general, the measurement instrument 10 is configured to analyze a measurement signal generated by a device under test or received from another electronic device. In some embodiments, the measurement instrument 10 is configured to determine a symbol error rate (SER) of the measurement signal, as is described in more detail hereinafter.

The measurement instrument 10 can be, for example, a signal analyzer, a spectrum analyzer, an oscilloscope, or a vector network analyzer. However, it is to be understood that the measurement instrument 10 may be established as any other suitable type of measurement instrument.

The measurement instrument 10 comprises a measurement input 12 being configured to receive the measurement signal. For example, the measurement input 12 may be connected to a device under test directly. As another example, the measurement input 12 may be connected to a measurement probe. Alternatively, the measurement input 12 may be connected to another electronic device, such as another measurement instrument or a server.

The measurement instrument 10 further comprises a reference signal input 14 being configured to receive a reference signal. Downstream of the measurement input 12 and of the reference signal input 14, a signal processing circuit 16 is provided. The signal processing circuit 16 is connected to each of the measurement input 12 and the reference signal input 14, such that the measurement signal and the reference signal are forwarded to the signal processing circuit 16. Optionally, the measurement instrument 10 may comprise a visualization circuit 18 being connected to the signal processing circuit 16 and/or a display 20 being connected to the visualization circuit 18.

FIG. 2 shows an embodiment of the signal processing circuit 16 in more detail. The signal processing circuit 16 comprises an input interface 22 that is connected to the measurement input 12 and the reference signal input 14 so as to receive the measurement signal (“meas”) and the reference signal (“ref”). The signal processing circuit 16 further comprises an analysis circuit 24 with a synchronization circuit 26, a symbol circuit 28, and a modulation circuit 30 that each are connected to the input interface 22. Downstream of the synchronization circuit 26, an error circuit 32 is provided.

Moreover, the analysis circuit 24 comprises a transformation circuit 34 that is provided downstream of the modulation circuit 30. The analysis circuit 24 further comprises an evaluation circuit 36 that is connected to each of the symbol circuit 28, the error circuit 32, and the transformation circuit 34.

It is noted that the signal processing circuit 16 may comprise more components than the ones described above. For example, the signal processing circuit 16 may comprise a radio frequency (RF) frontend and/or further signal shaping components, such as amplifiers, attenuators, filters, mixers, analog-to-digital converters, down-converters, up-converters, etc.

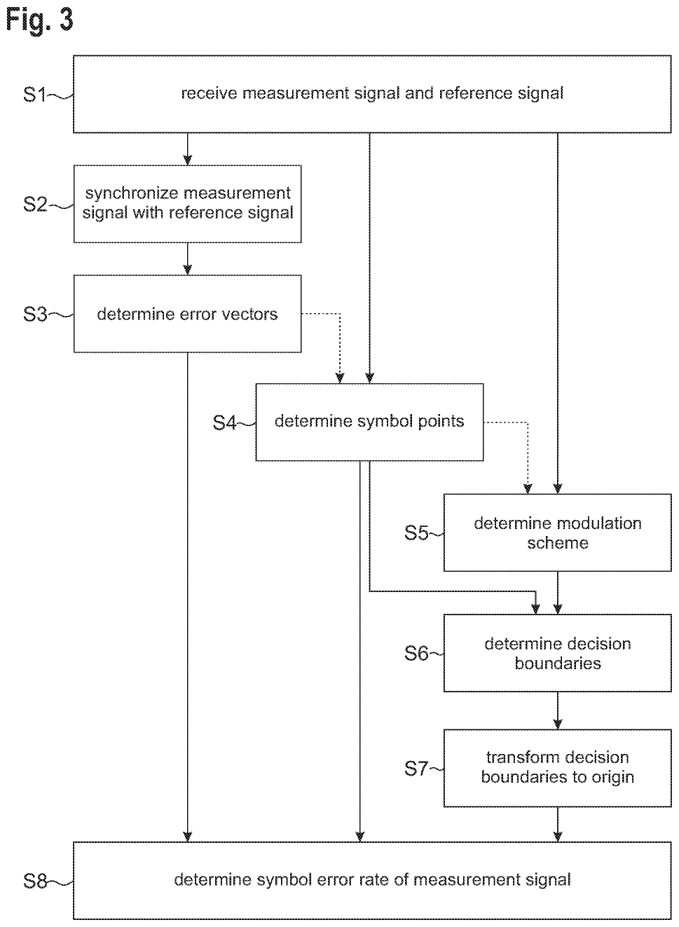

The measurement instrument 10 or the signal processing circuit 16 is configured to perform a method of determining an SER of a measurement signal, an example of which is described in the following with reference to FIG. 3.

A measurement signal and a reference signal are received by the input interface 22 (step S1). In general, the measurement signal and the reference signal are digital modulated signals, for example IQ-modulated signals, comprising a symbol sequence, respectively. In some embodiments, the measurement signal and the reference signal comprise the same symbol sequence.

The measurement signal may be an RF signal that is obtained by performing a measurement on a device under test that is connected to the measurement instrument 10. In this case, the reference signal may be a signal that is generated by an external signal generator and applied to an input of the device under test, i.e. the device under test processes the reference signal, thereby obtaining the measurement signal.

For example, a directional coupler may be provided between the input of the device under test and the external signal generator, wherein the directional coupler is configured to forward the reference signal to the device under test and to the reference signal input 14. However, it is also conceivable that the signal generator is integrated into the measurement instrument 10.

As another example, the reference signal may be a radio frequency signal obtained by a measurement. Alternatively, the measurement signal and the reference signal may be a digital file or a digital data stream. Thus, the measurement signal and the reference signal may be played back from a memory in which the digital file is saved. Alternatively, the measurement signal and the reference signal may be received from another electronic device streaming the digital data stream, e.g. from a server, a personal computer, a laptop, a smartphone, a tablet, from another measurement instrument, or from any other type of smart device.

The received measurement signal is forwarded to the synchronization circuit 26. Optionally, the received measurement signal may be forwarded to the symbol circuit 28 and/or to the modulation circuit 30. The received reference signal is forwarded to the synchronization circuit 26, to the symbol circuit 28, and to the modulation circuit 30.

The measurement signal is synchronized with the reference signal by the synchronization circuit 26 (step S2). In other words, the symbol sequences comprised in the measurement signal and in the reference signal are aligned with each other. It is emphasized that the measurement signal and the reference signal do not have to be demodulated in order to be synchronized.

In general, any suitable technique may be used in order to synchronize the measurement signal and the reference signal. For example, suitable techniques are described in granted patent U.S. Pat. No. 11,336,550 B2, which is hereby included in its entirety by reference. The synchronized measurement signal and reference signal are forwarded to the error circuit 32.

Error vectors are determined by the error circuit 32 based on the synchronized measurement signal and reference signal (step S3). In general, the error vectors correspond to a difference between the measurement signal and the reference signal. For example, the error vectors may be determined on a sample-by-sample basis, i.e. by subtracting the reference signal samples from the corresponding synchronized measurement signal samples. Accordingly, a corresponding error vector may be determined for each sample of the measurement signal.

The determined error vectors are forwarded to the evaluation circuit 36. Optionally, the determined error vectors may be forwarded to the symbol circuit 28.

Symbol points are determined by the symbol circuit 28 based on the reference signal, based on the measurement signal, and/or based on the error vectors (step S4). In general, any suitable technique may be used in order to determine the symbol points. For example, suitable techniques are described in granted patent U.S. Pat. No. 11,336,550 B2.

In a certain example, a user may manually enter the ratio between the symbol rate and the sample rate. This ratio is used to estimate the symbol instances (i.e. the symbol points). For example, if the sample rate is twice the symbol rate, it implies that there are two samples per symbol. Therefore, every second sample would correspond to a symbol instance.

In another example, a blind symbol rate estimator may be used to automatically determine the symbol rate. This is particularly useful when the symbol rate is unknown or cannot be manually entered. The blind symbol rate estimator works by analyzing the signal and identifying repeating patterns or features that correspond to the symbol rate. Once the symbol rate is estimated, it can be used to determine the symbol instances relative to the samples.

In another example, the reference signal may comprise a marker or a known feature. The marker or the known feature in the reference signal may be used to determine the symbol instances. The marker could be a specific symbol, a unique sequence of symbols, or a particular pattern in the signal. By identifying the occurrence of this marker in the signal, the symbol instances can be determined.

The determined symbol points are forwarded to the evaluation circuit 36 and to the modulation circuit 30.

A modulation scheme of the measurement signal is determined by the modulation circuit 30 based on the reference signal and/or based on the measurement signal (step S5). Optionally, the modulation scheme may be determined based on the determined symbol points.

Based on the determined modulation scheme and based on the determined symbol points, decision boundaries are determined for the individual symbols of the measurement signal by the modulation circuit 30 (step S6). In some embodiments, a respective decision boundary may be determined for each of the individual symbols of the measurement signal.

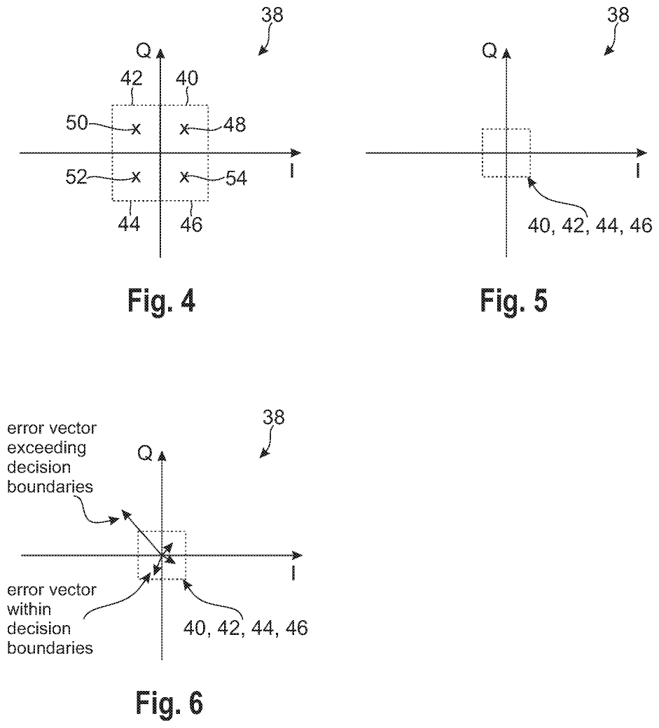

Step S6 is illustrated in FIG. 4, which shows a constellation plane 38 with the determined decision boundaries 40, 42, 44, 46 for the representative case of four different constellation points 48, 50, 52, 54 being possible in the measurement signal, i.e. for four different possible values of the individual symbols of the measurement signal. In the example embodiment shown in FIG. 4, the constellation plane is an IQ plane, i.e. the measurement signal is an IQ-modulated signal.

Usually, different modulation schemes have different decision boundaries associated with the symbols. By determining the modulation scheme, the decision boundaries can be determined by an appropriate method, e.g. by a lookup table comprising different modulation schemes and associated decision boundaries.

The determined decision boundaries are transformed to the origin of the constellation plane 38 by the transformation circuit 34 (step S7). As is illustrated in FIG. 5, the determined decision boundaries 40, 42, 44, 46 may be transformed such that geometric centers of the decision boundaries 40, 42, 44, 46 are shifted to the origin of the constellation plane 38. It is noted that while the example decision boundaries 40, 42, 44, 46 illustrated in FIGS. 4 and 5 all have the same size, it is also conceivable that the decision boundaries may have different sizes. The transformed decision boundaries are forwarded to the evaluation circuit 36.

An SER of the measurement signal is determined by the evaluation circuit 36 based on the transformed decision boundaries, based on the determined symbol points, and based on the determined error vectors (step S8). As is illustrated in FIG. 6, the evaluation circuit 36 determines the number of error vectors exceeding the determined decision boundaries at the symbol points. The SER of the measurement signal can then be determined by dividing the number of error vectors exceeding the decision boundaries at the symbol points by the total number of symbols analyzed, i.e. by the number of symbol points determined.

Optionally, visualization data associated with the determined SER may be generated by the visualization circuit 18, and the generated visualization data may be displayed on the display 20. In other words, the determined SER may be visualized on the display 20.

The present disclosure proposes a method that begins with the synchronization of a measurement signal to a known reference. This synchronization process is a crucial step in ensuring the accuracy of the subsequent symbol/bit error rate (BER/SER) measurements. The reference signal can be a digital representation, such as a file or stream, or it can be a measurement on an RF signal on a second channel. The measurement signal, on the other hand, is the signal that is being evaluated for symbol errors.

The synchronization process involves aligning the measurement signal with the reference signal in time. This is achieved by comparing the two signals and adjusting the timing of the measurement signal until it matches the reference signal. This process can be performed using various signal processing techniques, such as cross-correlation, which measures the similarity between the measurement signal and the reference signal as a function of the time-lag applied to one of them.

Once the measurement signal is synchronized with the reference signal, the complex error vector is evaluated. This involves calculating the difference between the measurement signal and the reference signal at each symbol point in time. The symbol points in time can be determined on either the measurement signal, the reference signal, or the error vector signal.

The synchronization process ensures that the symbol points in time on the measurement signal align with those on the reference signal, allowing for a more accurate evaluation of the error vector and, consequently, a more accurate determination of the SER/BER.

Certain embodiments disclosed herein include systems, apparatus, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

Various embodiments of the present disclosure or the functionality thereof may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably). Such non-transitory computer-readable storage media include all computer-readable media (including volatile and non-volatile media).

Embodiments of the present disclosure may also take the form of an apparatus, system, computing device, computing entity, and/or the like executing instructions stored on computer-readable storage media to perform certain steps or operations. The computer-readable media include cooperating or interconnected computer-readable media, which exist exclusively on a processing or processor system or distributed among multiple interconnected processing or processor systems that may be local to, or remote from, the processing or processor system. However, embodiments of the present disclosure may also take the form of an entirely hardware embodiment performing certain steps or operations.

Various embodiments are described above with reference to block diagrams and/or flowchart illustrations of apparatuses, methods, systems, and/or computer program instructions or program products. It should be understood that each block of any of the block diagrams and/or flowchart illustrations, respectively, or portions thereof, may be implemented in part by computer program instructions, e.g., as logical steps or operations executing on one or more computing devices. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein.

These computer program instructions may also be stored in one or more computer-readable memory or portions thereof, such as the computer-readable storage media described above, that can direct one or more computers or computing devices or other programmable data processing apparatus(es) to function in a particular manner, such that the instructions stored in the computer-readable memory produce an article of manufacture including computer-readable instructions for implementing the functionality specified in the flowchart block or blocks.

The computer program instructions may also be loaded onto one or more computers or computing devices or other programmable data processing apparatus(es) to cause a series of operational steps to be performed on the one or more computers or computing devices or other programmable data processing apparatus(es) to produce a computer-implemented process such that the instructions that execute on the one or more computers or computing devices or other programmable data processing apparatus(es) provide operations for implementing the functions specified in the flowchart block or blocks and/or carry out the methods described herein.

It will be appreciated that the term computer or computing device can include, for example, any computing device or processing structure, including but not limited to a processor (e.g., a microprocessor), a central processing unit (CPU), a graphical processing unit (GPU), a digital signal processor (DSP), an application-specific integrated circuit (ASIC), a field-programmable gate array (FPGA), a system on a chip (SoC), or the like, or any combinations thereof.

Accordingly, blocks of the block diagrams and/or flowchart illustrations support various combinations for performing the specified functions, combinations of operations for performing the specified functions and program instructions for performing the specified functions. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In some embodiments, one or more of the components referenced above include circuitry programmed to carry out one or more steps of any of the methods disclosed herein. In some embodiments, one or more computer-readable media associated with or accessible by such circuitry contains computer readable instructions embodied thereon that, when executed by such circuitry, cause the component or circuity to perform one or more steps of any of the methods disclosed herein.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A signal processing circuit, comprising: an input interface and an analysis circuit,
wherein the input interface is configured to receive a measurement signal and a reference signal, wherein the input interface is configured to forward the measurement signal and the reference signal to the analysis circuit,
wherein the measurement signal and the reference signal comprise a symbol sequence, respectively,
wherein the analysis circuit is configured to:
synchronize the measurement signal with the reference signal;
determine error vectors based on the synchronized measurement signal and reference signal;
determine symbol points of the symbol sequence and decision boundaries for the symbol points; and
determine whether the determined error vectors exceed the decision boundaries determined.

2. The signal processing circuit of claim 1, wherein the analysis circuit is configured to determine the number of error vectors exceeding the decision boundaries.

3. The signal processing circuit of claim 2, wherein the analysis circuit is configured to determine a symbol error rate (SER) based on the determined number of error vectors exceeding the decision boundaries.

4. The signal processing circuit of claim 1, wherein the analysis circuit is configured to determine a modulation scheme of the measurement signal based on the measurement signal and/or based on the reference signal.

5. The signal processing circuit of claim 4, wherein the decision boundaries are determined based on the determined modulation scheme.

6. The signal processing circuit of claim 1, wherein the signal processing circuit is configured to transform the determined decision boundaries to an origin of a constellation plane.

7. The signal processing circuit of claim 6, wherein the constellation plane is an IQ plane.

8. The signal processing circuit of claim 1, wherein the measurement signal is a digital file or a digital data stream.

9. The signal processing circuit of claim 1, wherein the measurement signal is a radio frequency signal obtained by a measurement, or wherein the reference signal is a radio frequency signal obtained by a measurement.

10. A measurement instrument, comprising a signal processing circuit according to claim 1.

11. The measurement instrument of claim 10, wherein the measurement instrument is a signal analyzer, a spectrum analyzer, an oscilloscope, or a vector network analyzer.

12. A method of determining a symbol error rate of a measurement signal, the method comprising the steps of
receiving, by an input interface, a measurement signal and a reference signal, wherein the measurement signal and the reference signal comprise a symbol sequence, respectively;
synchronizing, by an analysis circuit, the measurement signal with the reference signal;
determining, by the analysis circuit, error vectors based on the synchronized measurement signal and reference signal;
determining, by the analysis circuit, symbol points of the symbol sequence and decision boundaries for the symbol points; and
determining, by the analysis circuit, whether the determined error vectors exceed the decision boundaries determined.

13. The method of claim 12, wherein the number of error vectors exceeding the decision boundaries is determined by the analysis circuit.

14. The method of claim 13, wherein a symbol error rate (SER) is determined based on the determined number of error vectors exceeding the decision boundaries by the analysis circuit.

15. The method of claim 12, wherein a modulation scheme of the measurement signal is determined based on the measurement signal or based on the reference signal by the analysis circuit.

16. The method of claim 15, wherein the decision boundaries are determined based on the determined modulation scheme.

17. The method of claim 12, wherein the determined decision boundaries are transformed to an origin of a constellation plane by the analysis circuit.

18. The method of claim 17, wherein the constellation plane is an IQ plane.

19. The method of claim 12, wherein the measurement signal is a digital file or a digital data stream.

20. The method of claim 12, wherein the measurement signal is a radio frequency signal obtained by a measurement, or wherein the reference signal is a radio frequency signal obtained by a measurement.
